(19) United States
(12) Patent Application Publication
(10) Pub. No.: US 2017/0315193 A1
(43) Pub. Date: Nov. 2, 2017

(54) MAGNETIC RESONANCE FINGERPRINTING USING A SPIN-ECHO PULSE SEQUENCE WITH AN ADDITIONAL 180 DEGREE PULSE

(71) Applicant: KONINKLIJKE PHILIPS N.V., EINDHOVEN (NL)

(72) Inventors: THOMAS ERIK AMTHOR, EINDHOVEN (NL); MARIYA IVANOVA DONEVA, EINDHOVEN (NL); PETER KOKEN, EINDHOVEN (NL); JOCHEN KEUPP, EINDHOVEN (NL); PETER BOERNERT, EINDHOVEN (NL)

(73) Assignee: KONINKLIJKE PHILIPS N.V., EINDHOVEN (NL)

(21) Appl. No.: 15/526,058

(22) PCT Filed: Nov. 5, 2015
(86) PCT No.: PCT/EP2015/075775

§ 371 Date: May 11, 2017

(30) Foreign Application Priority Data
Nov. 14, 2014 (EP) 14193149.3

(51) Int. Cl. G01R 33/48; G01R 33/46; G01R 33/465; G01R 33/565

(52) U.S. Cl. CPC G01R 33/4828; G01R 33/56563; G01R 33/4625; G01R 33/465

(57) ABSTRACT

The invention provides for a magnetic resonance system (100) for acquiring a magnetic resonance data from a subject (118) within a measurement zone (108) according to a magnetic resonance fingerprinting technique. The pulse sequence comprises a train of pulse sequence repetitions (302, 304). Each pulse sequence repetition has a repetition time chosen from a distribution of repetition times. Each pulse sequence repetition comprises a radio frequency pulse (306) chosen from a distribution of radio frequency pulses. The distribution of radio frequency pulses cause magnetic spins to rotate to a distribution of flip angles, and each pulse sequence repetition comprises a sampling event (310) at a sampling time chosen from a distribution of sampling times. Each pulse sequence repetition of the pulse sequence comprises a first 180 degree RF pulse (308) performed at a first temporal midpoint between the radio frequency pulse and the sampling event to refocus the magnetic resonance signal. Each pulse sequence repetition of the pulse sequence comprises a second 180 degree RF pulse (309) performed at a second temporal midpoint between the sampling event and the start of the next pulse repetition.

### TECHNICAL FIELD OF THE INVENTION

The invention relates to magnetic resonance imaging, in particular techniques for performing magnetic resonance fingerprinting.

### BACKGROUND OF THE INVENTION

Magnetic Resonance (MR) fingerprinting is a new technique where a number of RF pulses, distributed in time, are applied such that they cause signals from different materials or tissues to have a unique contribution to the measured MR signal. A limited dictionary of precalculated signal contributions from a set or fixed number of substances is compared to the measured MR signals and within a single voxel the composition can be determined. For example if it is known that a voxel only contains water, fat, and muscle tissue the contribution from these three materials need only be considered and only a few RF pulses are needed to accurately determine the composition of the voxel.

The magnetic resonance fingerprinting technique was introduced in the journal article Ma et al., “Magnetic Resonance Fingerprinting,” Nature, Vol. 495, pp. 187 to 193, doi:10.1038/nature11971. The magnetic fingerprinting technique is also described in United States patent applications US 2013/0271132 A1 and US 2013/0265047 A1.

### SUMMARY OF THE INVENTION

The invention provides for a magnetic resonance imaging system, a computer program product and a method in the independent claims. Embodiments are given in the dependent claims.

The Nature article by Ma et al. introduces the basic idea of magnetic resonance fingerprinting and terminology which is used to describe this technique such as the dictionary, which is referred to herein as a “pre-calculated magnetic resonance fingerprinting dictionary,” a “magnetic resonance fingerprinting dictionary,” and a “dictionary.”

As will be appreciated by one skilled in the art, aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

Any combination of one or more computer readable medium(s) may be utilized. The computer readable medium may be a computer readable signal medium or a computer readable storage medium. A ‘computer-readable storage medium’ as used herein encompasses any tangible storage medium which may store instructions which are executable by a processor of a computing device. The computer-readable storage medium may be referred to as a computer-readable non-transitory storage medium. The computer-readable storage medium may also be referred to as a tangible computer readable medium. In some embodiments, a computer-readable storage medium may also be able to store data which is able to be accessed by the processor of the computing device. Examples of computer-readable storage media include, but are not limited to: a floppy disk, a magnetic hard disk drive, a solid state hard disk, flash memory, a USB thumb drive, Random Access Memory (RAM), Read Only Memory (ROM), an optical disk, a magneto-optical disk, and the register file of the processor. Examples of optical disks include Compact Disks (CD) and Digital Versatile Disks (DVD), for example CD-ROM, CD-RW, CD-R, DVD-ROM, DVD-RW, or DVD-R disks. The term computer readable-storage medium also refers to various types of recording media capable of being accessed by the computer device via a network or communication link. For example a data may be retrieved over a modem, over the internet, or over a local area network. Computer executable code embodied on a computer readable medium may be transmitted using any appropriate medium, including but not limited to wireless, wire line, optical fiber cable, RF, etc., or any suitable combination of the foregoing.

A computer readable signal medium may include a propagated data signal with computer executable code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

‘Computer memory’ or ‘memory’ is an example of a computer-readable storage medium. Computer memory is any memory which is directly accessible to a processor. ‘Computer storage’ or ‘storage’ is a further example of a computer-readable storage medium. Computer storage is any non-volatile computer-readable storage medium. In some embodiments computer storage may also be computer memory or vice versa.

A ‘processor’ as used herein encompasses an electronic component which is able to execute a program or machine executable instruction or computer executable code. References to the computing device comprising “a processor” should be interpreted as possibly containing more than one processor or processing core. The processor may for instance be a multi-core processor. A processor may also refer to a collection of processors within a single computer system or distributed amongst multiple computer systems. The term computing device should also be interpreted to possibly refer to a collection or network of computing devices each comprising a processor or processors. The computer executable code may be executed by multiple processors that may be within the same computing device or which may even be distributed across multiple computing devices.

Computer executable code may comprise machine executable instructions or a program which causes a processor to perform an aspect of the present invention. Computer executable code for carrying out operations for aspects of the present invention may be written in any combination of one or more programming languages, including an object oriented programming language such as Java, Smalltalk, C++ or the like and conventional procedural programming languages, such as the “C” programming language or similar programming languages and compiled into machine executable instructions. In some instances the computer executable code may be in the form of a high level language or in a pre-compiled form and be used in conjunction with an interpreter which generates the machine executable instructions on the fly.

The computer executable code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described with reference to flowchart illustrations and/or block diagrams of methods, apparatus (systems) and computer program products according to embodiments of the invention. It is understood that each block or a portion of the blocks of the flowchart, illustrations, and/or block diagrams, can be implemented by computer program instructions in form of computer executable code when applicable. It is further under stood that, when not mutually exclusive, combinations of blocks in different flowcharts, illustrations, and/or block diagrams may be combined. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks. A ‘user interface’ as used herein is an interface which allows a user or operator to interact with a computer or computer system. A ‘user interface’ may also be referred to as a ‘human interface device.’ A user interface may provide information or data to the operator and/or receive information or data from the operator. A user interface may enable input from an operator to be received by the computer and may provide output to the user from the computer. In other words, the user interface may allow an operator to control or manipulate a computer and the interface may allow the computer indicate the effects of the operator's control or manipulation. The display of data or information on a display or a graphical user interface is an example of providing information to an operator. The receiving of data through a keyboard, mouse, trackball, touchpad, pointing stick, graphics tablet, joystick, gamepad, webcam, headset, pedals, wired glove, remote control, and accelerometer are all examples of user interface components which enable the receiving of information or data from an operator.

A ‘hardware interface’ as used herein encompasses an interface which enables the processor of a computer system to interact with and/or control an external computing device and/or apparatus. A hardware interface may allow a processor to send control signals or instructions to an external computing device and/or apparatus. A hardware interface may also enable a processor to exchange data with an external computing device and/or apparatus. Examples of a hardware interface include, but are not limited to: a universal serial bus, IEEE 1394 port, parallel port, IEEE 1284 port, serial port, RS-232 port, IEEE-488 port, Bluetooth connection, Wireless local area network connection, TCP/IP connection, Ethernet connection, control voltage interface, MIDI interface, analog input interface, and digital input interface.

A ‘display’ or ‘display device’ as used herein encompasses an output device or a user interface adapted for displaying images or data. A display may output visual, audio, and or tactile data. Examples of a display include, but are not limited to: a computer monitor, a television screen, a touch screen, tactile electronic display, Braille screen,

Cathode ray tube (CRT), Storage tube, Bi-stable display, Electronic paper, Vector display, Flat panel display, Vacuum fluorescent display (VF), Light-emitting diode (LED) displays, Electroluminescent display (ELD), Plasma display panels (PDP), Liquid crystal display (LCD), Organic light-emitting diode displays (OLED), a projector, and Head-mounted display.

Magnetic Resonance (MR) data is defined herein as being the recorded measurements of radio frequency signals emitted by atomic spins using the antenna of a Magnetic resonance apparatus during a magnetic resonance imaging scan. Magnetic resonance data is an example of medical image data. A Magnetic Resonance Imaging (MRI) image is defined herein as being the reconstructed two or three dimensional visualization of anatomic data contained within the magnetic resonance imaging data. This visualization can be performed using a computer.

In one aspect the invention provides for a magnetic resonance imaging system for acquiring magnetic resonance data from a subject within a measurement zone. The magnetic resonance system comprises a memory for storing machine-executable instructions. The memory further stores pulse sequence instructions. The pulse sequence instructions contain instructions which are used to execute a so-called pulse sequence. A pulse sequence as used herein encompasses a set of instructions or control commands which cause the magnetic resonance imaging system to perform a magnetic resonance technique. The pulse sequence instructions comprise a train of pulse sequence repetitions. Each pulse sequence repetition has a repetition time chosen from a distribution of repetition times. Each pulse sequence repetition comprises a radio-frequency pulse chosen from a distribution of radio-frequency pulses. The distribution of radio-frequency pulses may be used to cause magnetic resonance spins to rotate by a distribution of different flip angles. The different radio-frequency pulses for instance may use a different amplitude, duration or shape to cause a particular magnetic spin to rotate by a particular or different flip angle. The different radio-frequency pulses may have a different effect on different types of magnetic spins and cause them to rotate by different distributions of flip angles.

Each pulse sequence repetition further comprises a sampling event where the magnetic resonance signal is sampled for a predetermined duration at a sampling time before the end of the pulse sequence repetition. The sampling time is chosen from a distribution of sampling times. The magnetic resonance data is acquired during the sampling event. Each pulse sequence repetition of the pulse sequence instructions comprises a first 180° radio-frequency pulse performed at a first temporal midpoint between the radio-frequency pulse and the sampling event to refocus the magnetic resonance signal. Each pulse sequence repetition of the pulse sequence instructions comprises a second 180° radio-frequency pulse performed at a second temporal midpoint between the sampling event and the start of the next pulse repetition.

A benefit of using the two 180° radio-frequency pulses may be that this may reduce the effect of inhomogeneities in the magnetic field used in the measurement zone.

The magnetic resonance system further comprises a processor for controlling the magnetic resonance system. Execution of the machine-executable instructions causes the processor to acquire the magnetic resonance data by controlling the magnetic resonance system with the pulse sequence instructions. Execution of the machine-executable instructions further causes the processor to calculate the abundance of each of the set of predetermined substances by comparing the magnetic resonance data with a magnetic resonance fingerprinting dictionary. The magnetic resonance fingerprinting dictionary contains a listing of calculated magnetic resonance signals in response to execution of the pulse sequence instructions for a set of predetermined substances.

When the pulse sequence instructions are executed the pulse sequence repetitions are executed one-by-one. This leads to data being acquired for each pulse sequence repetition during the sampling time. The magnetic resonance fingerprinting dictionary contains the expected magnetic resonance signal for a particular substance. The actual measured magnetic resonance signal in all of the sampling times is a combination of magnetic resonance signals from different substances. In the magnetic resonance fingerprinting technique a possible composition of different substances is considered. The possible fingerprint for each of the substances is compared to the actual measured substance and the composition of the substance can be deconvolved using the magnetic resonance fingerprinting dictionary.

Overall the magnetic resonance fingerprinting technique may be used to determine the composition of a subject with a reduced amount of data or magnetic resonance data being acquired. This may make the technique more rapid than conventional magnetic resonance techniques. The use of the two 180° radio-frequency pulses makes the technique more accurate and may reduce the amount of data that needs to be acquired. Normally, when a magnetic resonance fingerprinting dictionary is calculated, inhomogeneities in the magnetic field need to be taken into account. If the voxel size is small compared to the spatial field variations, a dictionary including calculated signal responses for a large number of different magnetic fields can provide a sufficiently good match. A larger voxel size may result in the fingerprint being essentially blurred for each of the set of predetermined substances. The use of the two 180° radio-frequency pulses may simplify the calculation of the magnetic resonance fingerprinting dictionary and may make the results more accurate.

In another embodiment the pulse sequence instructions cause the magnetic resonance imaging system to acquire the magnetic resonance data according to a magnetic resonance fingerprinting technique.

The pulse sequence instructions may contain instructions to perform the measurement of the magnetic resonance data at varying repetition times, varying flip angles and varying measurement times per pulse repetition. This may provide a useful distribution of pulse times that provide a good sampling and allow matching of the different components to the magnetic resonance fingerprinting dictionary.

The sequence of RF pulses (flip angles), the repetition times etc, can be random or pseudorandom. In a pseudorandom sequence of RF pulses or in RF pulses selected from a distribution of possible RF pulses the sequence of the RF pulses may be chosen such that it maximizes its encoding power to achieve the highest diversity between the potential MR responses for the different species. A main point is that the pulse sequence comprises a range of repetition times and flip angles instead of single values. This may be selected in a way that the resulting magnetic resonance signals are different for different tissues and resemble fingerprints.

The k-space sampling can be varied. For example uniform k-space sampling in one dimension, non-uniform k-space sampling in one dimension, and random k-space sampling in one dimension. When using a one dimensional slice selection, such as z-slice selection and sampling without x and y gradients (i.e., one whole z slice at a time), one might say that only a single point in k-space (the origin) is sampled. One could use the z gradient not for slice selection but for sampling k-space in z direction, again without x and y gradients. In this case, k-space would be one-dimensional and the sampling could be performed using a uniform or non-uniform distribution of points in k-space. In another embodiment the pulse sequence comprises a train of pulse repetitions. Each pulse repetition of the train of the pulse repetitions has a random distribution, a preselected duration from distribution of durations, or a pseudorandom duration. The preselected duration may be selected from the distribution such that the resulting train of RF pulses appears to be random or pseudo-random, but may be chose to also optimize other properties. For example as already mentioned above, the RF pulses may be chosen such that they maximize the sequence's encoding power to achieve the highest diversity between the potential MR responses for the different species.

In another embodiment the magnetic resonance system is an NMR spectrometer.

In another embodiment the magnetic resonance system is a magnetic resonance imaging system.

In another embodiment the measurement zone is an imaging zone.

In another embodiment the magnetic resonance imaging system further comprises a magnet for generating a magnetic field within the imaging zone. The magnetic resonance imaging system further comprises a magnetic field gradient system for generating a gradient magnetic field within the imaging zone to spatially encode the magnetic resonance data. The main magnetic field is often also referred to as the B0 magnetic field. The pulse sequence instructions further comprise instructions to control the magnetic field gradient system for performing spatial encoding of the magnetic resonance data during acquisition of the magnetic resonance data. The spatial encoding divides the magnetic resonance data into discrete voxels. This embodiment may be beneficial because it may provide a means for determining the spatial result composition of a subject more rapidly.

In another embodiment, the magnetic resonance system further comprises a magnet for generating a main magnetic field within the measurement zone.

In another embodiment execution of the machine-executable instructions further cause the processor to calculate the magnetic resonance fingerprinting dictionary by modeling each of the predetermined substances as a single spin with the Bloch equations for each of the discrete voxels. For example, in each of the discrete voxels a hypothetical spin can be modeled using the Bloch equations and a simulation of the magnetic resonance system using the pulse sequence instructions. The calculated magnetic resonance data at each of the sampling times is then the magnetic resonance fingerprinting dictionary for the particular type of spin that was modeled. This would function particularly well for the case where the measurement zone is only divided into a single voxel. It also applies to the case where there is no gradient magnetic field for spatial encoding. For example, the magnetic resonance system could be a so-called NMR system for doing a chemical analysis on a sample.

In another embodiment the method further comprises calculating the magnetic resonance fingerprinting dictionary by modeling each of the predetermined substances as between 5 and 1 spins with the Bloch equation for each of the discreet voxels.

In another embodiment the method further comprises calculating the magnetic resonance fingerprinting dictionary by modeling each of the predetermined substances with the Bloch equation for each of the discrete voxels.

In another embodiment, the spatial encoding is one-dimensional. The discrete voxels are a set of discrete slices. The method further comprises the step of dividing the magnetic resonance data into the set of slices. The abundance of each of the set of predetermined slices is calculated within each of the set of slices by comparing the magnetic resonance dictionary for each of the set of slices with the magnetic resonance fingerprinting dictionary.

In another embodiment, the spatial encoding is performed by controlling the magnetic field gradient system to produce a magnetic field gradient in only one predetermined direction during the execution of the pulse sequence. This may result in the magnetic resonance data being encoded in only one direction slice by slice. This may then be used to make a so-called magnetic resonance fingerprint chart. In a magnetic resonance fingerprint chart the abundance of each of the set of predetermined substances is calculated along a one-dimensional extension.

In another embodiment, the spatial encoding is performed by controlling the magnetic field gradient system to produce a one-dimensional readout gradient at least partially during the sampling time. This for instance may be used to generate a distribution of each of the substances along the dimension as a function of position. This also may be used to generate a magnetic resonance fingerprint chart.

In another embodiment, the spatial encoding is three-dimensional. The spatial encoding is performed by controlling the magnetic field gradient system to produce a three-dimensional gradient at least partially during the sampling time. This may be beneficial because the three-dimensional distribution of each of the predetermined substances can be determined for the subject in a spatially resolved manner.

In another embodiment, the spatial encoding is performed as a multi-slice encoding. The spatial encoding is performed by controlling the magnetic field gradient system to produce a slice-selecting gradient during the radio-frequency pulse. The spatial encoding may further be performed by controlling the magnetic field gradient system to produce a phase or slice selection gradient during the first 180° radio-frequency pulse. The spatial encoding is further performed by controlling the magnetic field gradient system to produce readout gradients during the sampling time.

In another embodiment, the spatial encoding is performed as a non-Cartesian spatial encoding. The spatial encoding is performed by controlling the magnetic field gradient system to produce a readout gradient during the sampling event which samples k-space in non-Cartesian order.

In another embodiment, the calculation of the abundance of each of the predetermined tissue types within each of the discrete voxels by comparing the magnetic resonance data for each of the discrete voxels with the pre-calculated magnetic resonance fingerprinting dictionary is performed by the following steps. First by expressing each magnetic resonance signal of the magnetic resonance data as a linear combination of the signal from each of the set of predetermined substances. The next step is to determine the abundance of each of the set of predetermined substances by solving the linear combination using a minimization technique.

In another embodiment, the least squares method could be modified such that negative values of a particular substance are rejected.

In another embodiment, execution of the instructions further cause the processor to repeat measurement of the magnetic resonance data of at least one calibration phantom. The at least one calibration phantom comprises a known volume of at least one of the set of predetermined substances.

When used with a system that measures the magnetic resonance data along one dimension, each of the calibration phantoms may have a calibration axis. In this case the at least one calibration phantom comprises a known volume of at least one of the set of predetermined substances when the calibration axis is aligned with the predetermined direction. In other cases for instance when the calibration phantom is used in a system where a three-dimensional or two-dimensional imaging is made, the predetermined substances may be distributed uniformly with known concentration within the calibration phantom.

In another aspect the invention provides for a computer program product comprising machine-executable instructions and pulse sequence instructions for execution by a processor controlling the magnetic resonance system. The magnetic resonance system may be used for acquiring magnetic resonance data from a subject within a measurement zone. The pulse sequence instructions cause the magnetic resonance system to acquire the magnetic resonance data according to a magnetic resonance fingerprinting technique. The pulse sequence instructions comprise a train of pulse sequence repetitions. Each pulse sequence repetition has a repetition time chosen from a distribution of repetition times. Each pulse sequence repetition comprises a radio-frequency pulse chosen from a distribution of radio-frequency pulses.

The distribution of radio-frequency pulses causes magnetic spins to rotate by a distribution of flip angles. Each pulse sequence repetition comprises a sampling event where the magnetic resonance signal is sampled for a predetermined duration at a sampling time before the end of the pulse sequence repetition. The sampling time is chosen from a distribution of sampling times. The magnetic resonance data is acquired during the sampling event. Each pulse sequence repetition of the pulse sequence instructions comprises a first 180° radio-frequency pulse performed at a first temporal midpoint between the radio-frequency pulse and the sampling event to refocus the magnetic resonance signal. Each pulse sequence repetition of the pulse sequence instructions comprises a second 180° radio-frequency pulse performed at a second temporal midpoint between the sampling event and the start of the next pulse repetition.

Execution of the machine-executable instructions causes the processor to acquire the magnetic resonance data by controlling the magnetic resonance system using or with the pulse sequence instructions. Execution of the machine-executable instructions further causes the processor to calculate the abundance of each of the set of predetermined substances by comparing the magnetic resonance data with a magnetic resonance fingerprinting dictionary. The magnetic resonance fingerprinting dictionary contains a listing of calculated magnetic resonance signals in response to execution of the pulse sequence instructions for a set of predetermined substances.

In another aspect the invention provides for a method of operating a magnetic resonance system for acquiring magnetic resonance data from a subject within a measurement zone. The magnetic resonance system comprises a memory for storing pulse sequence instructions. The pulse sequence instructions cause the magnetic resonance system to acquire the magnetic resonance data according to a magnetic resonance fingerprinting technique. The pulse sequence instructions comprise a train of pulse sequence repetitions. Each pulse sequence repetition has a repetition time chosen from a distribution of repetition times. Each pulse sequence repetition comprises a radio-frequency pulse chosen from a distribution of radio-frequency pulses.

The distribution of radio-frequency pulses cause magnetic spins to rotate by a distribution of flip angles. Each pulse sequence repetition comprises a sampling event where the magnetic resonance signal is sampled for a predetermined duration at a sampling time before the end of the pulse sequence repetition. The sampling time is chosen from a distribution of sampling times. The magnetic resonance data is acquired during the sampling event. Each pulse sequence repetition of the pulse sequence instructions comprises a first 180° radio-frequency pulse performed at a first temporal midpoint between the radio-frequency pulse and the sampling event to refocus the magnetic resonance signal. Each pulse sequence repetition of the pulse sequence instructions comprises a second 180° radio-frequency pulse performed at a second temporal midpoint between the sampling event and the start of the next pulse repetition.

The method comprises the step of acquiring the magnetic resonance data by controlling the magnetic resonance imaging system with the pulse sequence instructions. The method further comprises the step of calculating the abundance of each of the set of predetermined substances by comparing the magnetic resonance data with the magnetic resonance fingerprinting dictionary. The magnetic resonance fingerprinting dictionary contains a listing of calculated magnetic resonance signals in response to execution of the pulse sequence instructions for a set of predetermined substances.

It is understood that one or more of the aforementioned embodiments of the invention may be combined as long as the combined embodiments are not mutually exclusive.

### BRIEF DESCRIPTION OF THE DRAWINGS

In the following preferred embodiments of the invention will be described, by way of example only, and with reference to the drawings in which:

FIG. 1 illustrates an example of a magnetic resonance imaging system;

FIG. 2 illustrates a method of operating the magnetic resonance imaging system of FIG. 1;

FIG. 3 illustrates an example of a pulse sequence; and

FIG. 4 illustrates a further example of a pulse sequence.

### DETAILED DESCRIPTION OF THE EMBODIMENTS

Like numbered elements in these figures are either equivalent elements or perform the same function. Elements which have been discussed previously will not necessarily be discussed in later figures if the function is equivalent.

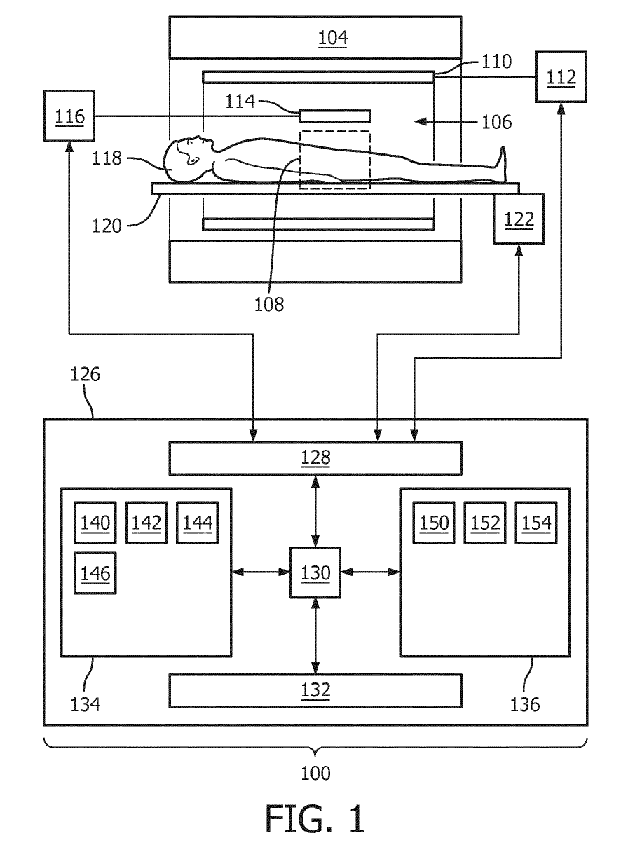

FIG. 1 shows an example of a magnetic resonance imaging system 100 with a magnet 104. The magnet 104 is a superconducting cylindrical type magnet 104 with a bore 106 through it. The use of different types of magnets is also possible; for instance it is also possible to use both a split cylindrical magnet and a so called open magnet. A split cylindrical magnet is similar to a standard cylindrical magnet, except that the cryostat has been split into two sections to allow access to the iso-plane of the magnet, such magnets may for instance be used in conjunction with charged particle beam therapy. An open magnet has two magnet sections, one above the other with a space in-between that is large enough to receive a subject: the arrangement of the two sections area similar to that of a Helmholtz coil. Open magnets are popular, because the subject is less confined. Inside the cryostat of the cylindrical magnet there is a collection of superconducting coils. Within the bore 106 of the cylindrical magnet 104 there is an imaging zone 108 where the magnetic field is strong and uniform enough to perform magnetic resonance imaging.

Within the bore 106 of the magnet there is also a set of magnetic field gradient coils 110 which is used for acquisition of magnetic resonance data to spatially encode magnetic spins within the imaging zone 108 of the magnet 104. The magnetic field gradient coils 110 connected to a magnetic field gradient coil power supply 112. The magnetic field gradient coils 110 are intended to be representative. Typically magnetic field gradient coils 110 contain three separate sets of coils for spatially encoding in three orthogonal spatial directions. A magnetic field gradient power supply supplies current to the magnetic field gradient coils. The current supplied to the magnetic field gradient coils 110 is controlled as a function of time and may be ramped or pulsed.

Adjacent to the imaging zone 108 is a radio-frequency coil 114 for manipulating the orientations of magnetic spins within the imaging zone 108 and for receiving radio transmissions from spins also within the imaging zone 108. The radio frequency antenna may contain multiple coil elements. The radio frequency antenna may also be referred to as a channel or antenna. The radio-frequency coil 114 is connected to a radio frequency transceiver 116. The radio-frequency coil 114 and radio frequency transceiver 116 may be replaced by separate transmit and receive coils and a separate transmitter and receiver. It is understood that the radio-frequency coil 114 and the radio frequency transceiver 116 are representative. The radio-frequency coil 114 is intended to also represent a dedicated transmit antenna and a dedicated receive antenna. Likewise the transceiver 116 may also represent a separate transmitter and receivers. The radio-frequency coil 114 may also have multiple receive/transmit elements and the radio frequency transceiver 116 may have multiple receive/transmit channels.

The subject support 120 is attached to an optional actuator 122 that is able to move the subject support and the subject 118 through the imaging zone 108. In this way a larger portion of the subject 118 or the entire subject 118 can be imaged. The transceiver 116, the magnetic field gradient coil power supply 112 and the actuator 122 are all see as being connected to a hardware interface 128 of computer system 126. The computer storage 134 is shown as containing pulse sequence instructions 140 for performing a magnetic resonance fingerprinting technique.

The pulse sequence instructions comprise a train of pulse sequence repetitions. Each pulse sequence repetition has a repetition time chosen from a distribution of repetition times. Each pulse sequence repetition comprises a radio-frequency pulse chosen from a distribution of radio-frequency pulses. The distribution of radio-frequency pulses may be used to cause magnetic resonance spins to rotate to a distribution of different flip angles. The different radio-frequency pulses for instance may use a different amplitude, duration or shape to cause a particular magnetic spin to rotate to a particular or different flip angle. The different radio-frequency pulses may have a different effect on different types of magnetic spins and cause them to rotate to different distributions of flip angles. Each pulse sequence repetition further comprises a sampling event where the magnetic resonance signal is sampled for a predetermined duration at a sampling time before the end of the pulse sequence repetition. The sampling time is chosen from a distribution of sampling times. The magnetic resonance data is acquired during the sampling event. Each pulse sequence repetition of the pulse sequence instructions comprises a first 180° radio-frequency pulse performed at a first temporal midpoint between the radio-frequency pulse and the sampling event to refocus the magnetic resonance signal. Each pulse sequence repetition of the pulse sequence instructions comprises a second 180° radio-frequency pulse performed at a second temporal midpoint between the sampling event and the start of the next pulse repetition. The computer storage 134 is further shown as containing magnetic resonance data 142 that was acquired using the pulse sequence instructions 140 to control the magnetic resonance imaging system 100. The computer storage 134 is further shown as containing a magnetic resonance fingerprinting dictionary 144. The computer storage is further shown as containing a magnetic resonance image 146 that was reconstructed using the magnetic resonance data 142 and the magnetic resonance fingerprinting dictionary 144.

The computer memory 136 contains a control module 150 which contains such code as operating system or other instructions which enables the processor 130 to control the operation and function of the magnetic resonance imaging system 100.

The computer memory 136 is further shown as containing a magnetic resonance fingerprint dictionary generating module 152. The fingerprint generating module 152 may model one or more spins using the Bloch equation for each voxel to construct the magnetic resonance fingerprinting dictionary 144. The computer memory 136 is further shown as containing an image reconstruction module that uses the magnetic resonance data 142 and the magnetic resonance fingerprinting dictionary 144 to reconstruct the magnetic resonance image 146. For example the magnetic resonance image 146 may be a rendering of the spatial distribution of one or more of the predetermined substances within the subject 118.

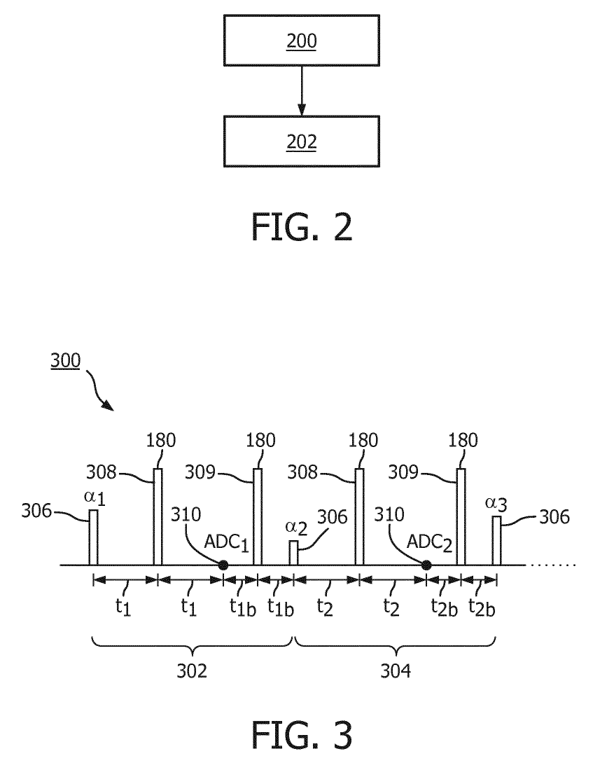

The example of FIG. 1 could be modified so that the magnetic resonance imaging system or apparatus 100 is equivalent to a Nuclear Magnetic Resonance (NMR) spectometer. Without gradient coils 110 and the gradient coil power supply 112 the apparatus 100 would perform a 0-dimensional measuremetn in the imaging zone 108. FIG. 2 shows a flowchart which illustrates a method of operating the magnetic resonance imaging system 100 of FIG. 1. First in step 200 the magnetic resonance data 142 is acquired by controlling the magnetic resonance imaging system with the pulse sequence instructions 140. Next in step 202 the abundance of each of the set of the predetermined substances is calculated by comparing the magnetic resonance data 142 with the magnetic resonance fingerprinting dictionary 144. The abundance for instance may be plotted or displayed in the magnetic resonance image 146.

Magnetic Resonance (MR) fingerprinting is a new and very promising technique for the determination of tissue types by comparison of an MR measurement to a number of pre-calculated dictionary entries.

This invention builds upon the idea of MR fingerprinting in combination with an MR of scanner of reduced complexity and dedicated sequences and reconstruction algorithms to open up new opportunities for very efficient cancer screening or quantitative large-volume measurements.

Magnetic resonance fingerprinting has a high potential for accurate tissue characterization. Still, the current technique is based on a voxel-wise analysis of MR images and therefore is both time-consuming and expensive.

Some examples may provide for a way to efficiently detect and quantify the existence of specific tissue types while:

1. Reducing hardware cost and energy consumption
2. Increasing patient throughput

This may enable new applications for early cancer detection or for body fat quantification.

Examples may possibly have one or more of the following features:

1. An MRI system with reduced hardware requirements: Low-performance x- and y-coils are possible; these coils may even be left out completely (a z-gradient coil can be designed to be very efficient).
2. A dedicated image acquisition sequence for B0-independent magnetic resonance fingerprinting
3. A dedicated reconstruction algorithm which determines relative and absolute volumes of different tissue types
4. A display device to visualize the findings

Instead of producing and analyzing medical images based on voxels, some example methods described here yields a tissue component analysis of a whole z-slice. A single dedicated fingerprint measurement (duration of a few seconds) is performed without employing in-plane (x, y) gradients. The tissue composition of the whole slice and the relative abundance of the tissue components are determined automatically from the resulting signal.

The MR sequence to be used preferably fulfills two requirements: First, it is sensitive to tissue-specific parameters (e.g. T1 and T2 values, others are conceivable, too) to encode the tissues of interest and allow quantitative tissue characterization by matching the measured signal against a dictionary (MR fingerprinting). Second, the signal is independent of non-tissue specific parameter variations (e.g. B₀ variations), so that matching the tissue components is possible over the whole slice.

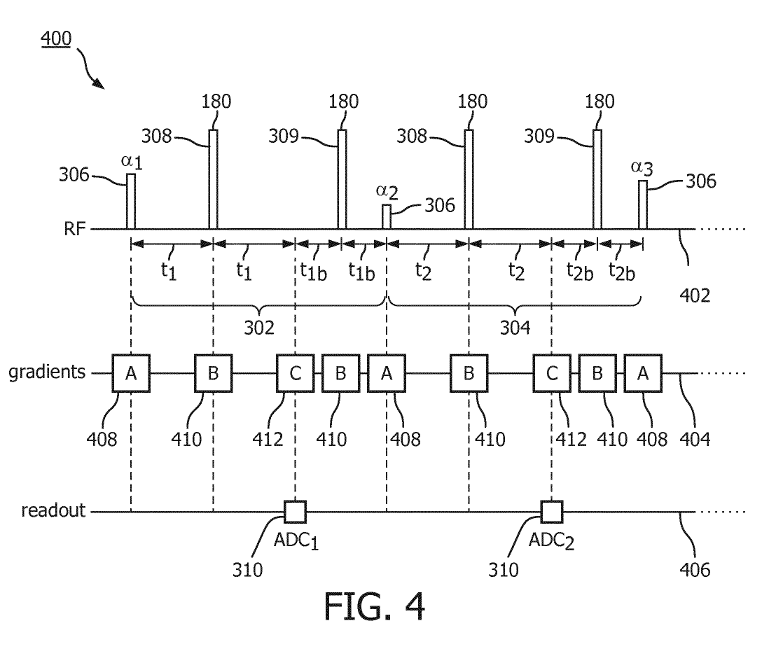

FIG. 4 illustrates one example of such a sequence, which is sensitive to T₁ and T₂ but independent of B₀ variations. The sequence is based on a random or otherwise freely chosen list of flip angles αᵢ and delay times tᵢ. After the first RF pulse with flip angle α1, an echo is produced after a delay of 2t₁ and the signal is recorded (ADC1). Another echo step with length 2t_{1b} ensures that the dephasing is again eliminated before the next part of the fingerprint sequence begins with flip angle α₂ and delay t₂.

The additional echoes after the measurement points ADCᵢ can be kept as short as possible with t_{1b}=t_{2b}= . . . A slice-selection gradient is switched on for each RF pulse using the z gradient coil.

FIG. 3 shows a portion an exemplary pulse sequence 300. The pulse sequence 300 may be used for generating or calculating the pulse sequence instructions 140. In this timing diagram a first pulse sequence repetition 302 is shown and a second pulse sequence repetition 304 is shown. Each pulse repetition begins with a radio-frequency pulse 306. The duration of the pulse repetition varies from pulse repetition to pulse repetition. There is a duration 310 where the radio-frequency signal is measured. The time between the radio-frequency pulse 306 and the measurement duration 310 is also varied as is the amplitude and/or shape of the particular radio-frequency pulses 306. This pulse sequence 300 also shows two 180° refocusing pulses 308, 309 per repetition 302, 304. The first refocusing pulse 308 is located at the temporal midpoint between the radio-frequency pulse 306 and the measurement duration 310. The second radio-frequency pulse 309 is located between the midpoint of the measurement duration 310 and the start of the next pulse 306. The first refocusing pulse 308 causes the radio-frequency signal to be refocused when the measurement 310 is made. The second refocusing pulse 309 causes the signal to be refocused when the next pulse 304 starts.

As in conventional MRF sequences, each sampling point ADCi may actually consist of a very fast series of multiple samplings of k-space. This may be Cartesian, spiral, or any other kind of k-space sampling.

The idea behind this sequence is the following: The refocusing 180-degree pulses 308, 309 ensure that at the time of the αᵢ, pulses and at the time of the samplings ADCi, all spins are refocused. The dephasing caused by Bₒ variations is therefore eliminated at the points in time of the αᵢ pulses and the ADCi samplings, rendering the measured signal independent of B₀. Additionally, a pre-calculation of the signal is simple when no dephasing effects need to be considered. In this case, the behavior of a single spin can be modelled, and for each time step t₁, t_{1b}, t₂, t_{2b}, etc., the evolution of the spin can be described by simple functions of the time constants T₁ and T₂.

The effect of using the two refocusing pulses 308 and 309 is that the effect of any inhomogeneities in the magnetic field is reduced or minimized. This may reduce the signal-to-noise in the end magnetic resonance fingerprinting chart and it also makes it easier to make the pre-calculated magnetic resonance fingerprinting dictionary. Without this compensation it may be necessary to include effects of the inhomogeneities in the calculations used to make the pre-calculated magnetic resonance fingerprinting dictionary.

With magnetic field gradients, the pulse sequence 300 illustrated in FIG. 3 may for instance be useful for a 0-dimensional measurement where the entire measurement zone or imaging zone has the data all acquired at once. The 0-dimensional measurement may for example be useful for a NMR spectrometer instead of a magnetic resonance imaging system. A more complicated pulse sequence may be constructed which includes magnetic field gradients for performing spatial encoding.

FIG. 4 shows a further example of a pulse sequence 400. In this example there are three different timelines shown. The first timeline 402 labels the radio-frequency pulse timeline. The timeline 404 shows when magnetic field gradients are applied. The third timeline labeled 406 shows when the measurements 310 are made. On the gradient timeline 404 there are three types of boxes labeled. The boxes labeled A 408, the boxes labeled B 410, and the boxes labeled C 412. The boxes labeled a 408 overlap with the radio-frequency pulses 306. The boxes labeled B overlap with the 180° radio-frequency pulses 308, 309. The boxes labeled C 412 overlap with the measurements 310. Each of the boxes represents a time period during which magnetic field gradients are set or varied according to the description of the different embodiments. In principle the radio-frequency timeline 402 can be used with most magnetic resonance techniques and k-space sampling schemes so as to enable a magnetic resonance fingerprinting technique to be applied using various magnetic resonance modalities or techniques.

For example if a constant magnetic field gradient were applied during the gradient timeline 404, there would be spatial encoding in slabs along the direction that the magnetic field gradient is applied. In another example a readout gradient may be applied only during the box C 412. For instance a one-dimensional or a three-dimensional readout gradient could be applied to obtain a one-dimensional or three-dimensional magnetic resonance fingerprint. In another example multi-slice encoding could be used. A slice-selecting gradient could be applied during the period a 408 during the radio-frequency pulse 306. The spatial encoding could further be performed by controlling the magnetic field gradient system to produce a phase or slice selection during the first 180° radio-frequency pulse 180. A readout gradient could then be applied during the time period C 412. Using the example shown in FIG. 4 it can be seen by the skilled individual how the base radio-frequency pulses illustrated in the timeline 402 could be applied in a general means to most magnetic resonance imaging sampling techniques.

The measured MR signal (a list of all the ADCᵢ values) may be compared with the pre-calculated dictionary for all combinations of T₁ and T₂ to be expected in the volume. The dictionary is created by solving the Bloch equations for the fingerprinting sequence described above for different combinations of T₁ and T₂.

In order to determine the tissue composition of the whole slice, the signal is expressed as a (complex) linear combination of the N dictionary entries,

s=Σₖ₌₀^{N}aₖdₖ

where s is the signal vector and dₖ are the dictionary entries. The coefficients aₖ≧0 are determined by the reconstruction algorithm. This is accomplished by solving the least squares problem
minimize

∥Da−s∥₂

for

aₖ≧0

where D is the dictionary matrix with dictionary entries dₖ as columns and a is the vector of coefficients describing the contribution of the individual potential tissues components/tissue types to the detected signal.

Each dictionary entry is assigned to a certain tissue type. Thus, the coefficients aₖ yield an estimate for the relative abundance of the different tissue components in terms of the “number of spins” involved for each component.

In a further step, these relative “spin numbers” can be converted estimates of relative volumes or relative masses of the tissue components if the spin density of the different tissue types is known.

In some examples, the system does not produce spatially resolved images. The only spatial resolution is achieved in the z-direction (or other single direction) by applying the RF pulses shown in FIG. 4 in a slice selective manner. However, for each slice, the composition of tissue types is determined and can be visualized as numbers, bar graphs, etc. In the case of a multi-slice scan, the abundance of the different components can be displayed as a function of the z position.

In other examples, the system may be programmed in such a way that it alerts the operator if certain types of tissue are found (e.g., suspicious masses, potential tumors). It can also be programmed in such a way that it displays the total volume/relative abundance of specified tissues, e.g. metastases of a certain kind or fat fraction.

In one example, the MRI system contains no x or y gradient coils. Only a z gradient coil is provided.

In one example, the MRI system contains no gradient coil at all. A static z gradient is provided by a dedicated MR magnet with asymmetric windings.

In one example, a slightly higher spatial resolution, preferable in-plane, could be achieved by using spatially sensitive local reception coils, which are placed closed to the body surface.

In one example, a number of measurements are performed, while the patient table is moved stepwise automatically. In this way, a large part of the body or the whole body can be scanned.

In another example, using moving table technology, the patient is moved through a sensitive receive array (“car-wash approach”) to improve spatial resolution and SNR and to reduce costs of too many receivers.

In one example, a gauge measurement using a known volume of a known substance is performed once to determine the factor of proportionality linking the volume/mass of the substance to the value of the relative volume/mass determined by measurement. In this way, all subsequently measured relative volumes/masses can be converted to absolute tissue volumes/masses.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

### LIST OF REFERENCE NUMERALS

100 magnetic resonance system
104 magnet
106 bore of magnet
108 measurement zone or imaging zone
110 magnetic field gradient coils
112 magnetic field gradient coil power supply
114 radio-frequency coil
116 transceiver
118 subject
120 subject support
122 actuator
124 predetermined direction
125 slices
126 computer system
128 hardware interface
130 processor
132 user interface
134 computer storage
136 computer memory
140 pulse sequence instructions
142 magnetic resonance data
144 magnetic resonance fingerprinting dictionary
146 magnetic resonance image
150 control module
152 magnetic resonance fingerprint dictionary generating module
154 image reconstruction module
300 pulse sequence instructions
302 first pulse sequence repetition
304 second pulse sequence repetition
306 RF pulse
308 first 180 degree refocusing pulse
309 second 180 degree refocusing pulse
310 measurement or radio frequency signal
400 pulse sequence
402 RF pulse timeline
402 magnetic field gradient timeline
404 readout timeline
408 time period A
410 time period B
412 time period C

1. A magnetic resonance system for acquiring a magnetic resonance data from a subject within a measurement zone, wherein the magnetic resonance system comprises:
a memory for storing machine executable instructions, and pulse sequence instructions, wherein the pulse sequence instructions cause the magnetic resonance system to acquire the magnetic resonance data according to a magnetic resonance fingerprinting technique, wherein the pulse sequence instructions comprises a train of pulse sequence repetitions, wherein each pulse sequence repetition has a repetition time chosen from a distribution of repetition times, wherein each pulse sequence repetition comprises a radio frequency pulse chosen from a distribution of radio frequency pulses, wherein the distribution of radio frequency pulses cause magnetic spins to rotate to a distribution of flip angles, and wherein each pulse sequence repetition comprises a sampling event where the magnetic resonance signal is sampled for a predetermined duration at a sampling time before the end of the pulse sequence repetition, wherein the sampling time is chosen from a distribution of sampling times, wherein the magnetic resonance data is acquired during the sampling event, wherein each pulse sequence repetition of the pulse sequence instructions comprises a first 180 degree RF pulse performed at a first temporal midpoint between the radio frequency pulse and the sampling event to refocus the magnetic resonance signal, and wherein each pulse sequence repetition of the pulse sequence instructions comprises a second 180 degree RF pulse performed at a second temporal midpoint between the sampling event and the start of the next pulse repetition in order to reduce the effect of inhomogeneities in the magnetic field used in the measurement zone;
a processor for controlling the magnetic resonance system, wherein execution of the machine executable instructions causes the processor to:
acquire the magnetic resonance data by controlling the magnetic resonance system with pulse sequence instructions; and
calculate the abundance of each of a set of predetermined substances by comparing the magnetic resonance data with a magnetic resonance fingerprinting dictionary, wherein the magnetic resonance fingerprinting dictionary contains a listing of calculated magnetic resonance signals in response to execution of the pulse sequence instructions for a set of predetermined substances.

2. The magnetic resonance system of claim 1, wherein the magnetic resonance system further comprises, wherein the magnetic resonance system is a magnetic resonance imaging system, wherein the measurement zone is an imaging zone:
a magnet for generating a main magnetic field within the measurement zone;
a magnetic field gradient system for generating a gradient magnetic field within the measurement zone to spatially encode the magnetic resonance data; and wherein the pulse sequence instructions further comprises instructions to control the magnetic field gradient system to for performing spatial encoding of the magnetic resonance data during acquisition of the magnetic resonance data, wherein the spatial encoding divides the magnetic resonance data into discrete voxels.

3. The magnetic resonance system of claim 2, wherein execution of the machine executable instructions further causes the processor to calculate the magnetic resonance fingerprinting dictionary by modeling each of the predetermined substances as a single spin with the Bloch equations for each of the discrete voxels.

4. The magnetic resonance system of claim 2, wherein the spatial encoding is one-dimensional, wherein the discrete voxels are a set of discrete slices, wherein the method further comprises the step of dividing the magnetic resonance data into the set of slices, wherein the abundance of each of a set of predetermined substances is calculated within each of the set of slices by comparing the magnetic resonance data for each of the set of slices with the magnetic resonance fingerprinting dictionary.

5. The magnetic resonance system of claim 4, wherein the spatial encoding is performed by controlling the magnetic field gradient system to produce a constant magnetic field gradient in a predetermined direction during the execution of the pulse sequence.

6. The magnetic resonance system of claim 4, wherein the spatial encoding is performed by controlling the magnetic field gradient system to produce a one dimensional readout gradient at least partially during the sampling event.

7. The magnetic resonance system of claim 2, wherein the spatial encoding is three dimensional, wherein the spatial encoding is performed by controlling the magnetic field gradient system to produce a three dimensional readout gradient least partially during the sampling event.

8. The magnetic resonance system of claim 2, wherein the spatial encoding is performed as multislice encoding, wherein the spatial encoding is performed by controlling the magnetic field gradient system to produce a slice selecting gradient during the radio frequency pulse, wherein the spatial encoding is further performed by controlling the magnetic field gradient system to produce a phase selection gradient or a slice selection gradient during the first 180 degree RF pulse, and wherein the spatial encoding is performed by controlling the magnetic field gradient system to produce a readout gradient during the sampling event.

9. The magnetic resonance system of claim 2, wherein the spatial encoding is performed as non-Cartesian spatial encoding, wherein the spatial encoding is performed by controlling the magnetic field gradient system to produce a readout gradient during the sampling event which samples k-space in a non-Cartesian order.

10. The magnetic resonance system of claim 1, wherein the magnetic resonance system is a NMR spectrometer, wherein execution of the machine executable instructions further causes the processor to calculate the magnetic resonance fingerprinting dictionary by modeling each of the predetermined substances as a single spin with the Bloch equations for each of the discrete voxels.

11. The magnetic resonance system of claim 1, wherein the calculation of the abundance of each of the predetermined tissue types within each of discrete voxels by comparing the magnetic resonance data for each of the discrete voxels with the pre-calculated magnetic resonance fingerprinting dictionary is performed by:
expressing each magnetic resonance signal of the magnetic resonance data as a linear combination of the signal from each of the set of predetermined substances, and
determining the abundance of each of the set of predetermined substances by solving the linear combination using a minimization technique.

12. The magnetic resonance system of claim 1, wherein execution of the instructions further causes the processor to repeat measurement of the magnetic resonance data of at least one calibration phantom, wherein the at least one calibration phantom comprises a known volume of at least one of the set of predetermined substances.

13. A computer program product storing machine executable instructions and pulse sequence instructions for execution by a processor for controlling a magnetic resonance system for acquiring magnetic resonance data from a subject within a measurement zone, wherein the pulse sequence instructions cause the magnetic resonance system to acquire the magnetic resonance data according to a magnetic resonance fingerprinting technique, wherein the pulse sequence instructions comprises a train of pulse sequence repetitions, wherein each pulse sequence repetition has a repetition time chosen from a distribution of repetition times, wherein each pulse sequence repetition comprises a radio frequency pulse chosen from a distribution of radio frequency pulses, wherein the distribution of radio frequency pulses cause magnetic spins to rotate to a distribution of flip angles, and wherein each pulse sequence repetition comprises a sampling event where the magnetic resonance signal is sampled for a predetermined duration at a sampling time before the end of the pulse sequence repetition, wherein the sampling time is chosen from a distribution of sampling times, wherein the magnetic resonance data is acquired during the sampling event, wherein each pulse sequence repetition of the pulse sequence instructions comprises a first 180 degree RF pulse performed at a first temporal midpoint between the radio frequency pulse and the sampling event to refocus the magnetic resonance signal, and wherein each pulse sequence repetition of the pulse sequence instructions comprises a second 180 degree RF pulse performed at a second temporal midpoint between the sampling event and the start of the next pulse repetition in order to reduce the effect of inhomogeneities in the magnetic field used in the measurement zone, wherein execution of the machine executable instructions causes the processor to:
acquire the magnetic resonance data by controlling the magnetic resonance system with pulse sequence instructions, and
calculate the abundance of each of a set of predetermined substances by comparing the magnetic resonance data with a magnetic resonance fingerprinting dictionary, wherein the magnetic resonance fingerprinting dictionary contains a listing of calculated magnetic resonance signals in response to execution of the pulse sequence instructions for a set of predetermined substances.

14. A method of operating a magnetic resonance system for acquiring magnetic resonance data from a subject within a measurement zone, wherein the magnetic resonance system comprises:
a memory for storing pulse sequence instructions, wherein the pulse sequence instructions cause the magnetic resonance system to acquire the magnetic resonance data according to a magnetic resonance fingerprinting technique, wherein the pulse sequence instructions comprises a train of pulse sequence repetitions, wherein each pulse sequence repetition has a repetition time chosen from a distribution of repetition times, wherein each pulse sequence repetition comprises a radio frequency pulse chosen from a distribution of radio frequency pulses, wherein the distribution of radio frequency pulses cause magnetic spins to rotate to a distribution of flip angles, and wherein each pulse sequence repetition comprises a sampling event where the magnetic resonance signal is sampled for a predetermined duration at a sampling time before the end of the pulse sequence repetition, wherein the sampling time is chosen from a distribution of sampling times, wherein the magnetic resonance data is acquired during the sampling event, wherein each pulse sequence repetition of the pulse sequence instructions comprises a first 180 degree RF pulse performed at a first temporal midpoint between the radio frequency pulse and the sampling event to refocus the magnetic resonance signal, and wherein each pulse sequence repetition of the pulse sequence instructions comprises a second 180 degree RF pulse performed at a second temporal midpoint between the sampling event and the start of the next pulse repetition in order to reduce the effect of inhomogeneities in the magnetic field used in the measurement zone;
wherein the method comprises the steps of:
acquiring the magnetic resonance data by controlling the magnetic resonance system with pulse sequence instructions; and
calculating the abundance of each of a set of predetermined substances by comparing the magnetic resonance data with a magnetic resonance fingerprinting dictionary, wherein the magnetic resonance fingerprinting dictionary contains a listing of calculated magnetic resonance signals in response to execution of the pulse sequence instructions for a set of predetermined substances.
